(19) United States
(12) Patent Application Publication
(10) Pub. No.: US 2009/0085031 A1
(43) Pub. Date: Apr. 2, 2009

(54) Wafer-Shaped Measuring Apparatus and Method for Manufacturing the Same

(75) Inventors: Kenji Matsuda, Hyogo (JP); Tomohide Minami, Hyogo (JP); Yoshiki Yamanishi, Hyogo (JP); Muneo Harada, Hyogo (JP)

Correspondence Address: MASUVALLEY & PARTNERS, 8765 AERO DRIVE, SUITE 312, SAN DIEGO, CA, 92123, US

(73) Assignee: Tokyo Electron Limited, Tokyo (JP)

(21) Appl. No.: 12/224,280

(22) PCT Filed: Mar. 14, 2007
(86) PCT No.: PCT/JP2007/055084

§ 371 Date: Aug. 22, 2008

(30) Foreign Application Priority Data
Mar. 16, 2006 (JP) 2006-073052

(51) Int. Cl. H01L 23/58; H01L 21/00

(52) U.S. Cl. 257/48; 438/54; 257/E21.001

(57) ABSTRACT

The present invention provides a temperature measuring apparatus with favorable temperature measuring performance and a method of manufacturing the same. A temperature measuring apparatus (10) provided with a temperature sensor (11) arranged on a bottom surface of a depressed section (12c) of a semiconductor wafer (12). The semiconductor wafer (12) and temperature sensor (11) are contacted together through a first contact layer (14) and second contact layer (24). The first and second contact layers (14) and (24) are formed from the same material, concretely a metal with high heat conductivity, and formed to provide virtually even thickness in surface direction. By such first and second contact layers (14) and (24), heat is conducted from the semiconductor wafer (12) to the temperature sensor (11) favorably. Therefore, the temperature measuring apparatus (10) has favorable temperature measuring performance.

### TECHNICAL FIELD

The present invention relates to a wafer-shaped measuring apparatus for measuring conditions of wafer processes, and method for manufacturing the same, particularly relates to a temperature measuring apparatus for measuring semiconductor wafers and a method for manufacturing the same.

### BACKGROUND ART

Conventionally, in a manufacturing process of semiconductor devices, processes for thermally treating a semiconductor wafer (hereinafter referred as a wafer), such as a heat treatment for drying after applying resist solution, a heat treatment after exposure (post exposure baking), and CVD treatment when forming a predetermined thin film on a wafer surface, have been performed. In order to improve yield, the temperature within the wafer surface needs to be as even as possible when performing these thermal treatments.

### DISCLOSURE OF INVENTION

### Problems to be Solved by the Present Invention

For example, in a hot plate unit, in which baking processes, such as post exposure baking, is performed, the uniformity in the temperature distribution of the hot plate is required for the reasons that temperature in the treatment affects the line width of a circuit pattern and so on. Therefore, in order to investigate whether the hot plate has a predetermined temperature distribution uniformity or not, the temperature distribution is conventionally measured by burying thermocouples into a plurality of measuring points on a dummy wafer for the temperature measurements and placing the dummy wafer for the temperature measurements on the hot plate (e.g. refer to Japanese Patent No. 2984060).

### SUMMARY OF THE INVENTION

By the way, in a case when the temperature measurement is performed by providing a temperature sensor, such as a thermocouple, so as to contact the wafer, a contact layer formed by adhesive to fix the temperature sensor between the temperature sensor and the wafer is normally formed. However, when this contact layer has factors that heat is not favorably conducted from the wafer to the temperature, such as a low thermal conductivity or unevenness in the thickness of this contact layer, a problem of difficulty in accurately measuring the temperature for each measuring point of the wafer may occur. As a result, the temperature distribution of the hot plate or the like can not be accurately measured and resulting in a problem of negatively affecting the treatments.

For this reason, a temperature measuring apparatus with favorable temperature measuring performance capable of favorably conducting heat from the wafer to the temperature sensor and a method for manufacturing the same has been desired.

The present invention has been made considering above situations, and an objective is to provided a temperature measuring apparatus with favorable temperature measuring performance capable of favorably conducting heat from the wafer to the temperature sensor and a method for manufacturing the same.

In order to achieve an above objective, the wafer-shaped measuring apparatus pertaining to an aspect of the present invention includes:

a wafer;

a substrate provided on the wafer;

a function layer which functions as a sensor, formed on one principal surface of the substrate;

a first contact layer formed on the wafer between the substrate and the wafer corresponding to an area in which the substrate is provided; and

a second contact layer formed on another principal surface of the substrate facing to the first contact layer;

wherein the first contact layer and the second contact layer are formed from the same material.

According to the present invention, by contacting the sensor on the wafer and wafer using a high thermal conductivity material, a wafer-shaped measuring apparatus with favorable measuring performance and a method for manufacturing the same can be provided.

### BRIEF DESCRIPTION OF THE DRAWINGS

FIG. 1 is a plane view illustrating a temperature measuring apparatus pertaining to an embodiment of the present invention.

FIG. 2 is an A-A line cross section diagram of the temperature measuring apparatus of FIG. 1.

FIG. 3 illustrates a temperature sensor provided in a temperature measuring apparatus pertaining to an embodiment of the present invention.

FIG. 4 illustrates a portion of wafer in which the temperature sensor of FIG. 3 is provided.

FIG. 5A illustrates a manufacturing method of temperature sensor pertaining to an embodiment of the present invention.

FIG. 5B illustrates a manufacturing method of temperature sensor pertaining to an embodiment of the present invention.

FIG. 6A illustrates a manufacturing method of temperature measuring apparatus pertaining to an embodiment of the present invention.

FIG. 6B illustrates a manufacturing method of temperature measuring apparatus pertaining to an embodiment of the present invention.

FIG. 6C illustrates a manufacturing method of temperature measuring apparatus pertaining to an embodiment of the present invention.

FIG. 7 illustrates X-ray diffraction pattern in a case when forming a platinum layers on four types of substrate.

### EXPLANATION OF SYMBOLS

10 TEMPERATURE MEASURING APPARATUS
11 TEMPERATURE SENSOR
12 SEMICONDUCTOR WAFER
14 FIRST CONTACT LAYER
16 WIRING
17 WIRE
18 FLAT CABLE
21 SUBSTRATE
22 PLATINUM LAYER
23 TERMINAL
24 SECOND CONTACT LAYER

### DETAILED DESCRIPTION OF INVENTION

A temperature measuring apparatus and a manufacturing method for the same according to embodiments of the present invention will be described referring to drawings.

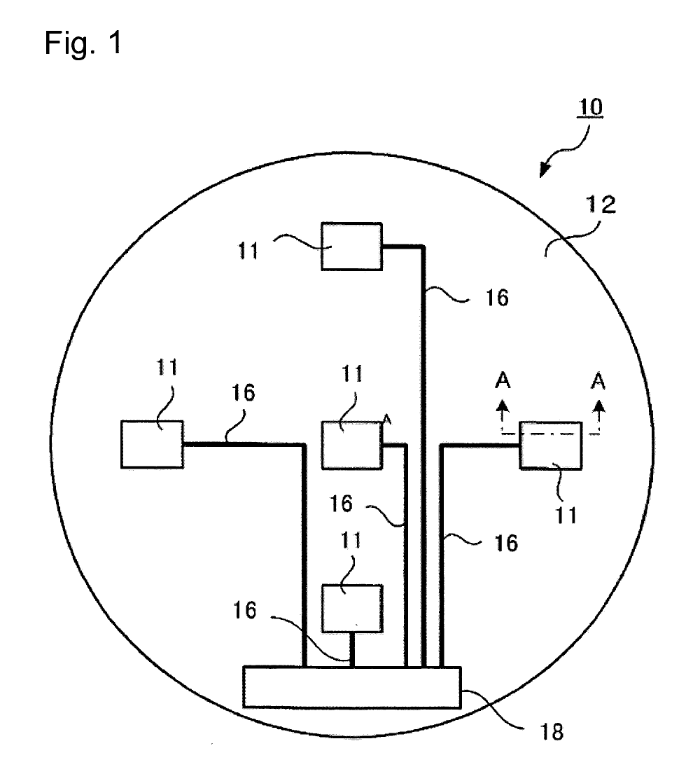

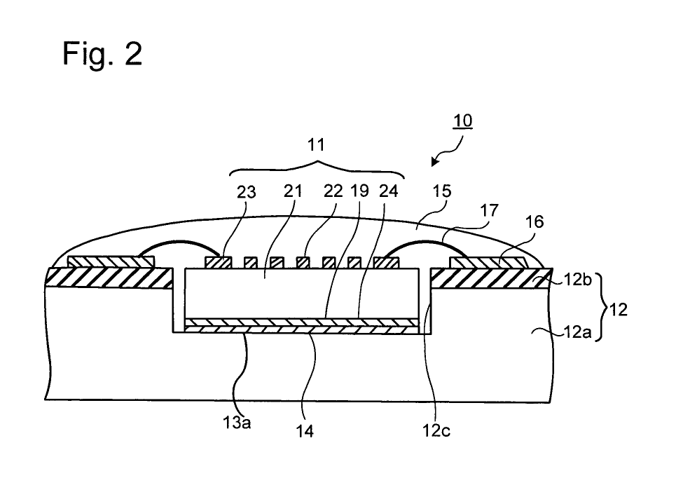

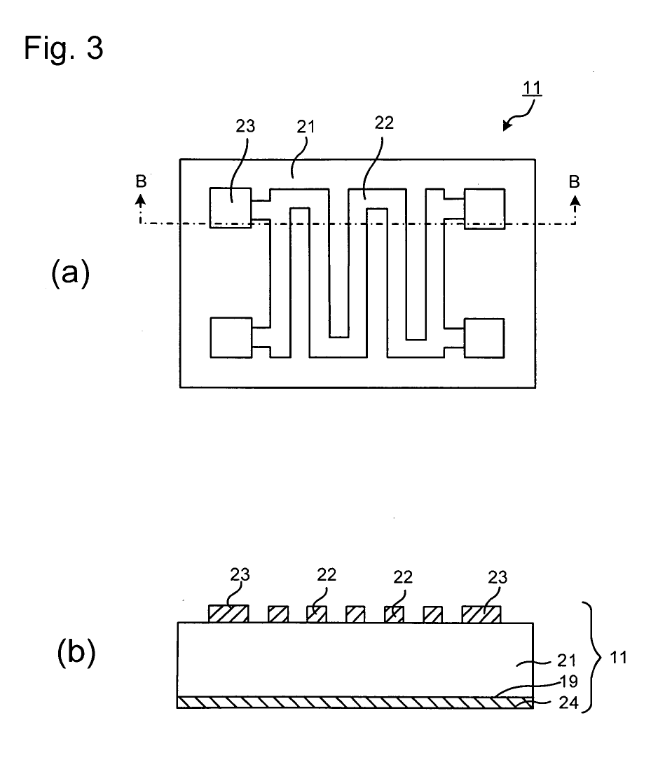

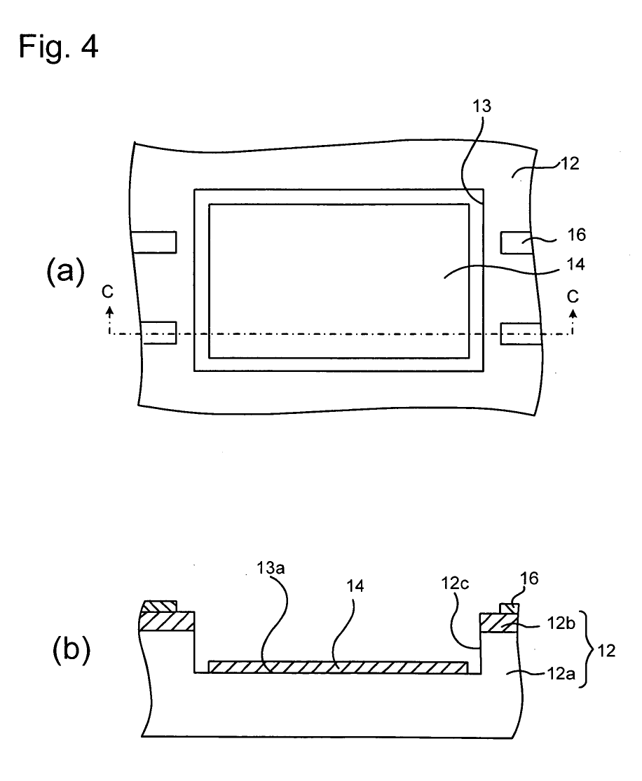

FIGS. 1 to 4 illustrate a temperature measuring apparatus 10 pertaining to an embodiment of the present invention. FIG. 1 is a plane view of the temperature measuring apparatus 10. FIG. 2 is an A-A line cross section diagram of the temperature measuring apparatus 10 in FIG. 1. FIG. 3(a) is a plane view of a temperature sensor 11, which configures the temperature measuring apparatus 10. FIG. 3(b) is a B-B line cross section diagram of FIG. 3(a). FIG. 4(a) is a plane view of a semiconductor wafer 12 in an area where the temperature sensor 11 is provided. FIG. 4(b) is a C-C line cross section of FIG. 4(a).

As shown in FIGS. 1 to 4, the temperature measuring apparatus pertaining to the embodiment includes the temperature sensor 11, the semiconductor wafer 12, a first contact layer 14, a protection film 15, a wiring 16, a wire 17 and a flat cable 18. The temperature measuring apparatus 10 is formed on the semiconductor wafer 12 and in a shape of wafer.

The temperature measuring apparatus 10 of the embodiment is used in a manufacturing process of semiconductor devices, for example, in a heat treatment for drying after applying a photo-resist solution, heat treatment after exposure (post exposure baking) and heat treatment for CVD treatment to form a predetermined thin film on the surface of wafer. Concretely, it is used in a hot plate unit, which is used in a bake treatment, such as the post exposure baking, to verify if the hot plate has uniformity in temperature distribution.

As shown in FIGS. 1 to 3, the temperature sensor 11 is provided with a substrate 21, a platinum layer 22, a terminal 23 and a second contact layer 24. The temperature sensor 11 is a so-called platinum resistance temperature detector for measuring temperature utilizing that the resistance of the platinum linearly changes depending of temperature. The temperature sensor 11 is connected to four wirings 16 though the wire 17 as shown in FIG. 2. In this way, effects from the resistance value of the wiring 16 can be removed by using such four-probe method.

In addition, in an embodiment of the present, a configuration is adopted, such that placing the substrate 21 on the semi conductor wafer 12 after forming the platinum layer 22. With respect to a method for measuring a semiconductor wafer, a method can also be considered, in which forming the platinum layer 22, which functions as a platinum resistance temperature detector, directly on the semiconductor wafer 12. However, the manufacturing efficiency is low and there is a problem of increasing manufacturing cost because it is necessary to apply sputtering and patterning processes for each semiconductor wafer. Therefore, as described in detail later, a configuration of forming and cutting out a plurality of temperature sensors 11 on the wafer and placing them on the semiconductor wafer 12 is adopted in this embodiment.

The substrate 21 is made of a silicon single crystal substrate, and the platinum layer 22 is formed on the top surface of the substrate 21.

As shown in FIGS. 3(a) and 3(b), the platinum layer 22 is formed in a switch back form on the upper surface of the substrate 21. Also, two positions of terminals 23 are provided on the both ends of the platinum layer 22. In addition, the terminals 23 are electrically connected to the wirings 16 formed on the semiconductor wafer 12 by the wire 17.

The second contact layer 24 is formed from a high thermal conductivity material, and is formed from a metal, such as gold or copper. In this embodiment, concretely, gold is used as the second contact layer 24. The second contact layer 24 is formed on a bottom surface of the substrate 21 as shown in FIG. 2 and FIG. 3(b). The second contact layer 24 is formed on a lower surface of the substrate 21 through a second adhesion layer (not shown) made of chromium and the like to improve adhesiveness with the substrate 21. In addition, the first contact layer 14 formed on the semiconductor wafer 12 and the second contact layer 24 are formed from an identical material. Further, the second contact layer 24 is contacted to the first contact layer 14 by pressure as described later. By forming the first and second contact layers 14 and 24 from the identical material and further by contacting them by pressure as described in detail later, the second contact layer 24 and the first contact layer 14 are favorably contacted with substantially uniform thickness in the surface direction, thereby heat is conducted from the semiconductor wafer 12 to the temperature sensor 11 evenly and favorably.

The semiconductor wafer 12 is made form a silicon layer 12a and a SiO₂ layer 12b. As shown in FIG. 1, the temperature sensors 11 are arranged evenly on a center area and peripheral area of the semiconductor wafer 12, and the temperature sensor 11 is placed in a depressed section 12c provided on the semiconductor wafer 12 as shown in FIG. 2. Further, the depth of the depressed section 12c is substantially equal to the height of the temperature sensor 11, concretely, it is formed in about 30 μm to 200 μm. Therefore, the upper surface of the temperature sensor 11 and the upper surface of the semiconductor wafer 12 are in substantially the same plane as shown in FIG. 2. Further, as shown in FIG. 4(b) the first contact layer 14 is formed on the bottom surface of the depressed section 12c, in other word, in the area where the temperature sensor 11 is provided.

In addition the number or arrangement of the temperature sensor 11 shown in FIG. 1 is only an example, and it may be arranged in five or more, or less than five. Further, in this embodiment, the configuration in which the temperature sensor 11 is provided in the depressed section 12c provided on the semiconductor wafer 12, was described as an example; however, the temperature sensor 11 may be arranged on the first contact layer 14 after forming the first contact layer 14 on the upper surface of the semiconductor wafer 12 without providing the depressed section 12c on the semiconductor wafer 12. In such a case, the temperature sensor 11 is arranged so as to protrude comparing to the upper surface of the semiconductor wafer 12.

The protection film 15 is formed, for example, from a ceramic series protection material and is formed so as to cover the temperature sensor 11, a wire 17, and a wiring 16 that are provided on the semiconductor wafer 12. By the protection film 15, the temperature sensor 11 and so on are protected from an external environment, thereby a stable operation can be provided.

The wiring 16 is formed from a conductive material and is formed on the semiconductor wafer 12 as shown in FIG. 1. One end of the wiring 16 is connected to the terminal 23 of the temperature sensor 11 through the wire 17, and the other end is connected to the flat cable 18. In addition, as described above, since the temperature sensor 11 connected at four positions to measure the resistance with the four-probe method, four wirings 16 are formed against one temperature sensor 11; however, the four wiring 16 are shown collectively in one line in FIG. 1 for the convenience of explanation. The change in resistance value of the platinum layer 22 of the temperature sensor 11 is measured with measuring section (not shown) which is externally provided, from the terminal 23 of the platinum layer 22 via wire 17, wiring 16 and flat cable 18. The measuring section determines the temperature of semiconductor wafer 12 on the area where each of temperature sensors 11 is provided, based on the resistance value of the platinum layer 22. In addition, the wire 17 electrically connects the wiring 16 and terminal 23 by wire bonding.

As described above, in this embodiment, the semiconductor wafer 12 and the temperature sensor 11 can be contacted favorably by using the same high thermal conductivity material to the first contact layer 14 and the second contact layer 24, and the first contact layer 14 and the second contact layer 24 have substantially an even thickness because they are further contacted by the pressure contact. Therefore, the uneven heat conduction from the semiconductor wafer 12 to the temperature sensor 11 is less likely to occur and the heat is favorably conducted. Consequently, the temperature measuring apparatus 10 is provided with favorable temperature measuring performance.

Especially when the first contact layer 14 and the second contact layer 24 are formed from gold, they are rigidly contacted and heat conductivity and electric conductivity can be maintained very high because the surface can be stably maintained without oxidizing. As a result, favorable characteristics of the temperature sensor 11 can be obtained. Further, in a case when the surface of the semiconductor wafer 12 and the height of the temperature sensor are configured the same by forming the depressed section 12c on the semiconductor 12 and inserting the temperature sensor therein, an accurate measurement can be performed because the condition that is the same condition when measuring with an actual wafer can be simulated.

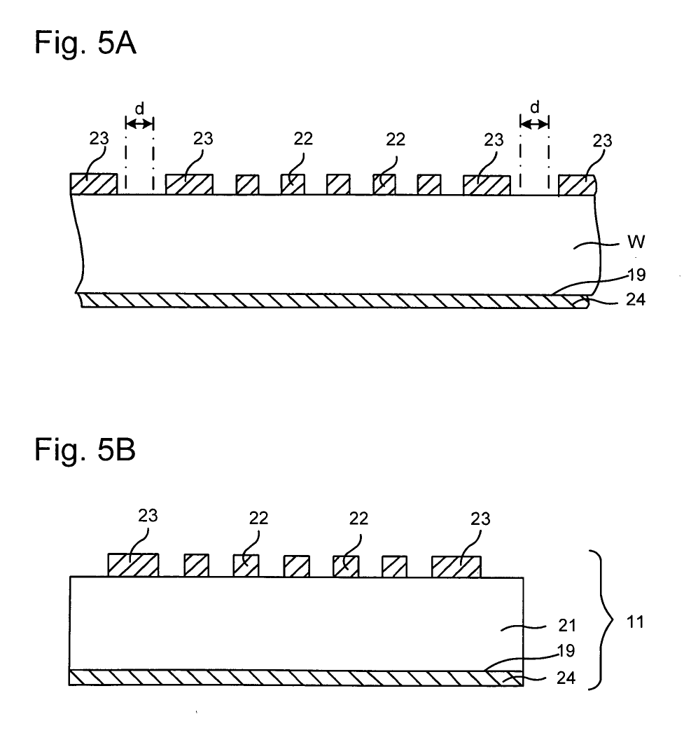

Next, a manufacturing method of the temperature measuring apparatus 10 pertaining to the embodiment of the present invention will be described referring to drawings. FIG. 5A is a cross-section diagram illustrating a condition where a plurality of temperature sensors 11 is formed on a wafer W.

Prepare the wafer W having an area where the plurality of temperature sensors 11 can be formed. And, a second adhesion layer (not shown) made from nickel or chromium, is formed on a lower surface of the wafer W by sputtering or the like. Next, onto the second adhesion layer, the second contact layer 24 structured by a high thermal conductivity material, such as gold, is formed by sputtering or plating as show in FIG. 5A Next, the platinum layer 22 in a switch back shape is formed on the wafer W by sputtering, ion milling and so on. Also, the terminal 23 is formed simultaneously with the platinum layer 22. Next, cut the wafer along a predetermined dicing line d to obtain the plurality of temperature sensors 11 as shown in FIG. 5B.

The plurality of temperature sensors 11 is formed at the same time in this way, the plurality of temperature sensors 11 with even characteristics can be obtained. Then, the plurality of temperature sensors 11 with even characteristics is contacted to the wafer W, thus, the temperature measuring apparatus 10 having the plurality of temperature sensors 11 with even characteristics can be formed. Especially, the plurality of temperature sensors 11 of the second contact layer 24 is formed in the same process, thus the contact sections for the plurality of temperature sensors 11 have even thermal conductivity characteristics when contacting the plurality of temperature sensors 11 to the semiconductor wafer 12 after cutting out by dicing. Further, the height of the temperature sensors 11 are even. Thereby the measuring accuracy is further increased.

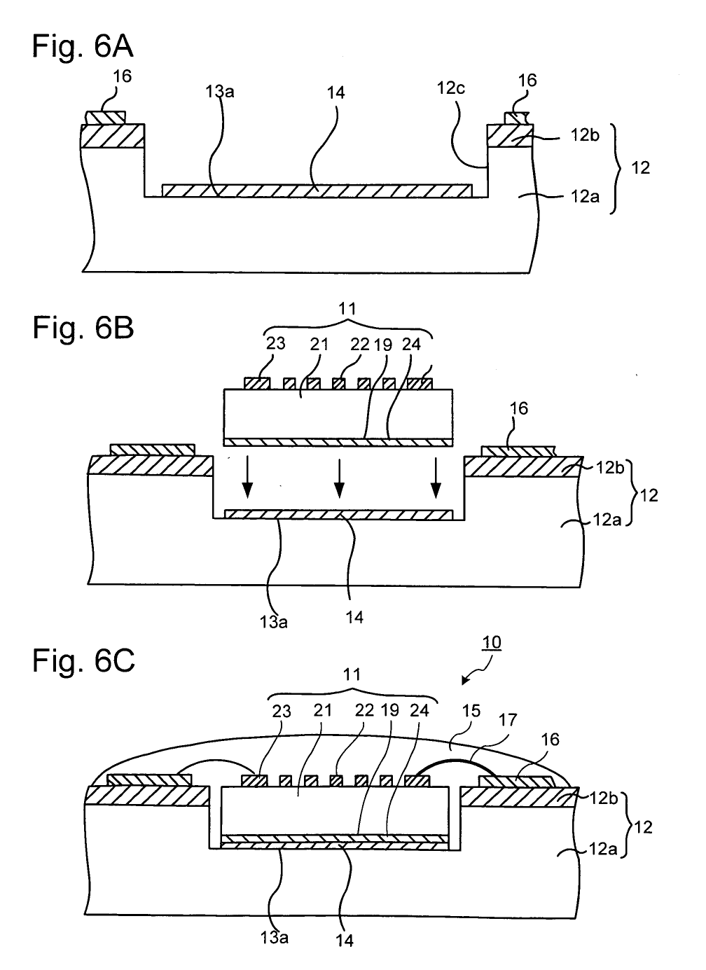

FIGS. 6A to 6C are illustrating the manufacturing method for the temperature measuring apparatus 10 pertaining to the embodiment of the present invention. FIG. 6A is a cross section diagram illustrating processing of the wafer 12. The depressed section 12c having substantially the same thickness of the temperature sensor 11 is formed on the area where the temperature sensor 11 of the semiconductor wafer 12 is provided by photolithography, etching and so on. Further, the wiring 16 as shown in FIG. 1 is formed on the semiconductor wafer 12 by sputtering and so on.

Next, the first adhesion layer (not shown) made of nickel, chromium or the like is formed on the bottom surface of the depressed section 12, that is the surface where the temperature sensor 11 is provided, by plating, sputtering or the like to provide favorable adhesiveness for the first contact layer 14 and semiconductor wafer 12. Next, onto the upper surface of the first adhesion layer, formed is the first contact layer 14 made from a high thermal conductivity material such as gold, by sputtering and so on as shown in FIG. 6A. In addition, the same material is used for the first contact layer 14 and the second contact layer 24.

FIG. 6B is a cross section diagram, which illustrates contact of the temperature sensor 11 to the semiconductor wafer 12. The semiconductor wafer 12, in which the temperature sensor 11 is arranged so as to contact the second contact layer 24 on the first contact layer 14, is placed on a lower plate of a press apparatus (not shown). Next, the temperature in the apparatus is increased by a heater provided to the press apparatus to soften the first contact layer 14 and the second contact layer 24. Next, substantially even pressure perpendicular to the semiconductor wafer 12 and in surface direction is applied to the temperature sensor 11 by an upper plate provided facing to and parallel to the lower plate. When a predetermined time is elapsed after applying the pressure, the heating in the apparatus by the heater is stopped and naturally cooled down to a room temperature. Thereby, the first contact layer 14 and second contact layer 24 are contacted so that they have substantially even thickness. In addition, the temperature in the press apparatus, the speed of raising temperature, the speed of lowering temperature, pressure, the time to apply pressure can be changed as necessary depending on the thickness, material and so on of the first contact layer 14 and the second contact layer 24.

Next, the terminal 23 and the wiring 16 provided on the semiconductor wafer 12 are electrically connected by the wire 17. Further, the wiring 16 and flat cable 18 are electrically connected. Next, the protection film 15 structured by polyimide, oxide layer, nitride film or the like is formed so as to cover the temperature sensor 11, wiring 16, wire 17 and so on.

From the process described above, the temperature measuring apparatus 10 is formed as shown in FIG. 6C.

As described above, in the manufacturing method for the temperature measuring apparatus 10 pertaining to the embodiment, the second contact layer 24 with high heat conductivity made of, for example, gold, is formed on the lower surface of the substrate 21 of the temperature sensor 11. And the first contact layer 14 is formed with the same material as the second contact layer 24 on the bottom surface of the depressed section 12c formed on the semiconductor wafer 12. Then, they are contacted by maintaining the pressure applied to them under a high temperature. Thereby, the contact surface of the temperature sensor 11 and the semiconductor wafer 12 is formed tightly and the thickness is formed substantially even. Thus, the unevenness of the thermal conduction of the temperature sensor 11 to the platinum layer 22 can be suppressed. Therefore the responsiveness of the platinum layer 22 improves and the temperature measuring apparatus 10 is provided with favorable temperature measuring performance.

In the embodiment, the temperature sensor 11 is formed by forming the plurality of platinum layers 22 and the second contact layer 24 on the wafer W and cutting them out. Thereby, the plurality of temperature sensors can be simultaneously formed. Thus improvement in manufacturing efficiency and further reduction of manufacturing cost can be realized. Because, in a case of configuration different from that of the embodiment, for example, when a platinum layer, which functions as a temperature sensor, is directly formed on a semiconductor wafer to form a temperature measuring apparatus, processes such as sputtering or patterning needs to be applied to the entire semiconductor wafer to form the temperature sensor. For example, even in a case when arranging five temperature sensors 11 on the semiconductor wafer 12 as shown in the embodiment, the process such as sputtering or patterning of the platinum onto the entire semiconductor wafer 12 is still necessary. Therefore, comparing to the method in which the plurality of temperature sensors 11 is formed on the wafer W and cutting them out, a large amount of material such as platinum or resist is necessary, and there is a problem of decreasing in manufacturing efficiency and increasing of cost.

Further, in this embodiment, by forming the substrate 21 of the temperature sensor 11 relatively thin, the thermal conduction to the platinum layer 22 is favorably provided, thereby the responsiveness of the platinum layer 22 can further be increased.

Therefore, according to the manufacturing method of the embodiment, the temperature measuring apparatus having favorable temperature measuring performance can be manufactured.

The present invention is not limited to the embodiments described above and various modification and application can be made. For example, in the embodiments described above describes the case where a silicon substrate is used as the substrate 21. However, a sapphire substrate may be used as the substrate 21. In such a case, the sapphire substrate is preferably formed thin such that the thermal conduction is provided favorably to the platinum layer 22 and the platinum layer 22 accurately responds to the temperature of the semiconductor wafer 12 and it is formed, for example, in 30 μm to 200 μm.

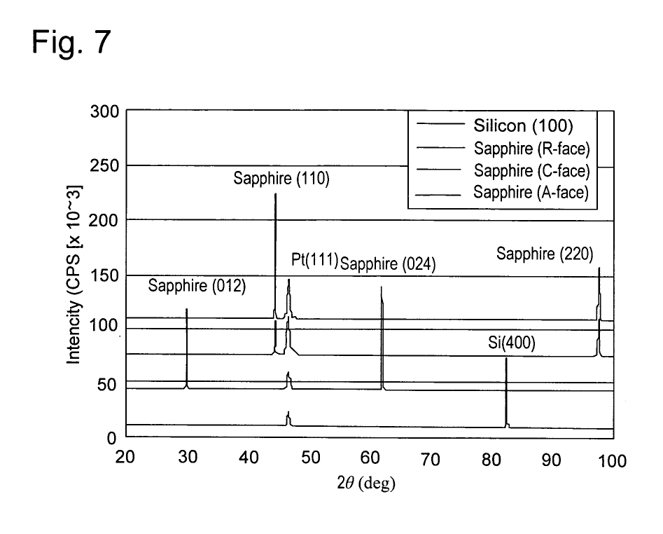

FIG. 7 illustrates a X-ray diffraction pattern in a case forming a platinum layer on each of A surface, C surface or R surface sapphire single crystal substrate, and in a case when forming a platinum layer on a silicon substrate (Si/SiO₂). In addition, in the X-ray diffraction pattern shown in FIG. 7, the platinum layer is not patterned. As apparent from FIG. 7, the peak of Pt (111) appears higher for the case where the platinum layer is formed on a sapphire substrate and the orientation of this surface increases comparing to the case of silicon substrate. The Pt (111) peak is especially high when the platinum layer is formed on the C-surface sapphire substrate and A-surface sapphire substrate, thus it can be appreciated that the Pt (111) surface has high orientation. Further, it can be noted that the C-surface has slightly higher orientation between C-surface and A surface. Therefore, by using the C-surface or A-surface sapphire single silicon substrate as the substrate 21, the platinum layer 22 with high orientation in (111) surface can be formed.

By using the sapphire substrate as the substrate 21, the orientation of the platinum layer 22 increases, thereby the temperature coefficient of resistance (TCR) improves. In addition, the temperature coefficient of resistance may also be increased in a case when the platinum layer is formed on the substrate with sputtering, by applying heat treatment after patterning. However, wire breaking may occur when a pattern size becomes fine due to aggregation of Pt caused from the heat treatment. Because, the platinum layer 22 is provided with high orientation of (111) surface and the temperature coefficient of resistance (TCR) increases favorably by forming the platinum layer on the sapphire substrate, the heat treatment after the patterning can be omitted and the wire breaking due to aggregation of Pt can be avoided in the case when the pattern size of the platinum layer is fine.

In this way, by using the A-surface single crystal sapphire substrate or a C-surface single crystal sapphire substrate as the substrate 21 configuring the temperature sensor 11, the orientation of the platinum layer 22 can be increased. Thus, the temperature coefficient of resistance of the platinum layer 22 incases and the responsiveness of the platinum layer 22 to the temperature improves, thereby the temperature measuring apparatus 10 is provided with further favorable temperature measuring performance.

### INDUSTRIAL APPLICABILITY

The present invention can be applied to a wafer-shaped measuring apparatus using a sensor other than temperature sensor 11. For example, instead of the temperature sensor 11, a flow sensor is formed with a substrate and it may be contacted to the semiconductor wafer 12. In such a case, when the surface of the substrate of flow sensor is formed substantially flat by inserting the substrate into the depressed section of the semiconductor wafer 12, it can be considered as the same shape with a wafers that actually processed. Thus, the flow in a chamber is same as when inserting the wafer. As a result, the condition in which the same as that of measuring with an actual wafer, can be simulated, and an accurate measurement can be performed. Alternatively, the present invention can be applied to a sensor applying the change in capacitance, or a sensor for measuring stress-strain. This embodiment is explained using the semiconductor wafer 12. However, a wide range of wafer-shaped material can be used and not limited to the semiconductor wafer 12 as a main substrate of the wafer-shaped measuring apparatus. Other than the silicon wafer, a substrate of liquid crystal device can be used for measuring a manufacturing process of the liquid crystal device. In such a case, it is preferable to form the substrate in the same shape as a wafer used in manufacture.

It should be understood that the embodiments disclosed herein are only exemplary in all aspects and should not be considered as limitations. The scope of the present invention is indicated by the scope of claims, and intended to include equal meaning of the scope of claims and all changes within the scope of claims.

This application is based on Japanese Patent application No. 2006-073052, filed on Mar. 16, 2006. The specification, claims, and drawings of the Japanese patent application No. 2006-073052 are incorporated herein by reference in its entirety.

1. A wafer-shaped measuring apparatus comprising:
a wafer;
a substrate provided on the wafer;
a function layer formed on one principal surface of the substrate and functions as a sensor;
a first contact layer formed on the wafer between the substrate and the wafer corresponding to an area in which the substrate is provided; and
a second contact layer formed on another principle surface of the substrate facing to the first contact layer;
wherein the first contact layer and the second contact layer are formed from the same material.

2. The wafer-shaped measuring apparatus according to claim 1,
wherein the substrate is provided on a bottom surface of a depressed section formed on the wafer, and
the first layer is formed on the bottom surface of the depressed section of the wafer.

3. The wafer-shaped measuring apparatus according to claim 2,
wherein a depth of the depressed section formed on the wafer and a thickness of the substrate are formed substantially the same.

4. The wafer-shaped measuring apparatus according claim 1,
wherein the first contact layer and the second contact layer are structured by gold or copper.

5. The wafer-shaped measuring apparatus according to claim 1, wherein the substrate is a silicon wafer.

6. The wafer-shaped measuring apparatus according to claim 1, wherein the function layer formed on one of the principal surface of the substrate is a platinum layer, which functions as a resistance temperature detector.

7. The wafer-shaped measuring apparatus according to claim 6, wherein the substrate is an A-surface sapphire single crystal substrate or a C-surface sapphire single crystal substrate.

8. The wafer-shaped measuring apparatus according to claim 1, wherein a first adhesion layer is formed between the first contact layer and wafer.

9. The wafer-shaped measuring apparatus according to claim 1, wherein a second adhesion layer is formed between the second contact layer and the substrate.

10. The wafer-shaped measuring apparatus according to claim 1, wherein the substrate provided on the wafer is configured by a plurality of substrates.

11. The wafer-shaped measuring apparatus according to claim 10, wherein second contact layers formed on the plurality of substrates are formed in the same process.

12. A method for manufacturing a wafer-shaped measuring apparatus, the method comprising the steps of:
forming a function layer which functions as a sensor on one principal surface on a substrate;
forming a first contact layer corresponding to an area where the substrate is provided on a wafer;
forming a second contact layer on the other principal surface of the substrate; and
contacting the first layer and the second layer;
wherein the same material is used for the step for forming the first contact layer and the step for forming the second contact layer.

13. The method for manufacturing the wafer-shaped measuring apparatus according to claim 12 further comprising the steps of:
forming a depressed section corresponding to an area where the substrate is provided, on the wafer;
wherein the first contact layer is formed on a bottom surface of the depressed section formed on the wafer in the step for forming the first contact layer.

14. The method for manufacturing the wafer-shaped measuring apparatus according to claim 13, wherein a depth of the depressed section and a thickness of the substrate are formed substantially the same in the step of forming the depressed section.

15. The method for manufacturing the wafer-shaped measuring apparatus according to claim 12, the first contact layer and the second contact layer are formed by using gold or copper in the steps of forming the first contact layer and the second contact layer.

16. The method for manufacturing the wafer-shaped measuring apparatus according claim 12, wherein a silicon wafer is used as the substrate.

17. The method for manufacturing the wafer-shaped measuring apparatus according to claim 12, wherein the step for forming the function layer is to form a platinum layer which functions as a resistance temperature detector on one principal surface of the substrate.

18. The method for manufacturing the wafer-shaped measuring apparatus according to claim 17, wherein an A-surface sapphire single crystal substrate or a C-surface sapphire single crystal substrate is used as the substrate.

19. The method for manufacturing the wafer-shaped measuring apparatus according to claim 12, wherein the step for forming the first contact layer further includes the step of forming a first adhesion layer between the first contact layer and the wafer.

20. The method for manufacturing the wafer-shaped measuring apparatus according to claim 12, wherein the step for forming the second contact layer further includes the step of forming a second adhesion layer between the second contact layer and the substrate.

21. The method for manufacturing the wafer-shaped measuring apparatus according to claim 12, wherein the step for forming the function layer forms functions layers to a plurality of substrates by the same process;
the step for forming the second contact layer forms second contact layers to the plurality of substrates by the same process;
the step for forming the first contact layer forms first contact layers correspond to the plurality of areas in which the substrate is provided on the wafer; and
the step for contacting the first layer and the second layer is to contact the first contact layers and the second contact layers fox the plurality of substrates.
